(19) United States
(12) Patent Application Publication
(10) Pub. No.: US 2017/0098622 A1
(43) Pub. Date: Apr. 6, 2017

(54) SEMICONDUCTOR DEVICE, SEMICONDUCTOR PACKAGE INCLUDING THE SAME, AND METHOD OF FABRICATING THE SAME

(71) Applicant: Samsung Electronics Co., Ltd., Suwon-si (KR)

(72) Inventors: Dong-Sik PARK, Suwon-si (KR); KYEHEE YEOM, Suwon-si (KR)

(21) Appl. No.: 15/286,811

(22) Filed: Oct. 6, 2016

(30) Foreign Application Priority Data
Oct. 6, 2015 (KR) 10-2015-0140538

(51) Int. Cl. H01L 23/00; H01L 23/498

(52) U.S. Cl. CPC H01L 24/08; H01L 23/49827; H01L 23/49894; H01L 24/48; H01L 23/49811; H01L 2224/08112; H01L 2224/48227

(57) ABSTRACT

A semiconductor device, a semiconductor package including the same, and a method of fabricating the same are disclosed. The method may include providing an integrated circuit on a semiconductor chip substrate; providing a first conductive pad on the substrate, the first conductive pad electrically connected to the integrated circuit chip; forming a first insulating layer on the substrate to cover the first conductive pad; forming a mask pattern on the first insulating layer, the mask pattern including an opening vertically overlapping the first conductive pad; removing a portion of the first insulating layer above the first conductive pad by performing etching using the mask pattern, thereby forming an opening in the first insulating layer; depositing an aluminum-containing conductive layer on the mask pattern, such that the mask pattern is between the first insulating layer and the aluminum-containing conductive layer, and such that the aluminum-containing conductive layer fills at least part of the opening and is connected to the first conductive pad; and patterning the aluminum-containing conductive layer to form a conductive pattern

### CROSS-REFERENCE TO RELATED APPLICATIONS

This U.S. non-provisional patent application claims priority under 35 U.S.C. §119 to Korean Patent Application No. 10-2015-0140538, filed on Oct. 6, 2015, in the Korean Intellectual Property Office, the entire contents of which are hereby incorporated by reference.

### BACKGROUND

This disclosure relates to a semiconductor chip with a redistribution layer, a semiconductor package including the same, and a method of fabricating the same.

Due to their small-size, multifunctionality, and/or low-cost characteristics, semiconductor devices are important elements in the electronic industry. Generally, semiconductor devices are classified into a memory device for storing data, a logic device for processing data, and a hybrid device for performing various functions.

As the electronic industry advances, there is an increasing demand for a semiconductor device with a higher integration density and higher performance. To meet such a demand, it is helpful to reduce a process margin (for example, in a photolithography process). Although a variety of studies are being conducted to solve the difficulties, the reduction of the process margin may lead to several difficulties in fabricating a semiconductor device.

In the meantime, various package technologies have been developed to meet demands for large capacity, thin thickness, and small size of semiconductor devices and/or electronic appliances. For example, a package technology of vertically stacking semiconductor chips has been used to allow an electronic product to have high density and large capacity features. The use of this package technology may allow many kinds of semiconductor chips to be integrated on a reduced area, when compared to a general package with a single semiconductor chip.

### SUMMARY

Some embodiments of the inventive concept provide a semiconductor device such as a semiconductor chip with a redistribution layer formed using a deposition and patterning process.

Some embodiments of the inventive concept provide a method of fabricating a semiconductor device with a redistribution layer, using a deposition and patterning process.

Some embodiments of the inventive concept provide a semiconductor package, in which a semiconductor chip with a redistribution layer is provided.

According to some embodiments of the inventive concept, a semiconductor device may include an integrated circuit on a semiconductor chip substrate, a pad electrically connected to the integrated circuit, a lower insulating structure having a contact hole exposing the pad, and a conductive pattern including: a contact portion filling at least part of the contact hole, a conductive line portion provided on the lower insulating structure to extend in a specific direction, and a bonding pad portion. The contact portion may have a first thickness at a horizontal portion in a direction perpendicular to a top surface of the substrate and a second thickness at a vertical portion in another direction parallel to the top surface of the substrate, and here, the first thickness may be greater than the second thickness. The lower insulating structure may include a plurality of lower inorganic insulating layers sequentially stacked on the substrate and a first polymer layer on the lower inorganic insulating layers. The semiconductor device may be a semiconductor chip.

In some embodiments, the first polymer layer may include poly(4-hydroxystyrene) (PHS) or polyimide.

In some embodiments, the first polymer layer may include a recess region, and when viewed in a plan view, the recess region does not overlap the conductive pattern.

In some embodiments, when viewed in a plan view, the first polymer layer may overlap the conductive pattern, and a sidewall of the first polymer layer may be aligned with that of the conductive pattern.

In some embodiments, the contact portion may be provided to fill at least a portion of the contact hole and define a recessed region.

In some embodiments, the pad may be electrically connected to the integrated circuit thereunder through a plurality of metal layers and a plurality of vias.

In some embodiments, when viewed in a plan view, the pad may be provided on a center area of the semiconductor chip substrate and the bonding pad portion may be provided on a peripheral area of the semiconductor chip subsrate.

In some embodiments, the semiconductor device may further include an upper insulating structure having a first opening exposing the bonding pad portion. The upper insulating structure may include an upper insulating layer covering the lower insulating structure and the conductive pattern and a second polymer layer on the upper insulating layer.

In some embodiments, the upper insulating layer may be provided to directly cover top and side surfaces of the conductive pattern.

In some embodiments, the upper insulating layer may include a silicon nitride layer, a silicon oxide layer, or a silicon oxynitride layer.

In some embodiments, the second polymer layer may include polyimide, fluoro carbon, resin, or synthetic rubber.

In some embodiments, the upper insulating structure may further include a second opening exposing the contact portion.

In some embodiments, each of the lower inorganic insulating layers may include a silicon nitride layer, a silicon oxide layer, or a silicon oxynitride layer.

In some embodiments, the lower inorganic insulating layers may include first to third lower insulating layers sequentially stacked on the substrate. Each of the first and third lower inorganic insulating layers may include a silicon oxide layer, and the second lower insulating layer may include a silicon nitride layer.

In some embodiments, the integrated circuit may include a memory cell of a dynamic random access memory (DRAM) device.

In some embodiments, the conductive pattern may include an aluminum-containing material.

In some embodiments, a width of the contact hole may be smaller than that of the first opening, when measured in the specific direction.

According to some embodiments of the inventive concept, a semiconductor device may include an integrated circuit on a semiconductor chip substrate, a pad electrically connected to the integrated circuit, a lower insulating structure having a contact hole exposing the pad, a conductive pattern including a contact portion filling at least part of the contact hole, a conductive line portion provided on the lower insulating structure to extend in a specific direction, and a bonding pad portion, and an upper insulating structure having an opening exposing the bonding pad portion. The lower insulating structure may include a plurality of lower inorganic insulating layers sequentially stacked on the substrate and a first polymer layer on the lower inorganic insulating layers. The upper insulating structure may include an upper insulating layer covering the lower insulating structure and the conductive pattern and a second polymer layer on the upper insulating layer. The first polymer layer may include a recess region that does not overlap the conductive pattern, when viewed in a plan view.

In some embodiments, the upper insulating layer may be provided to cover and contact side and bottom surfaces of the recess region.

According to some embodiments the semiconductor device includes a package substrate, wherein the integrated circuit and semiconductor chip substrate form a semiconductor chip provided on the package substrate, and the semiconductor chip is electrically connected to the package substrate with a wire. The semiconductor chip may include first and second surfaces opposite each other, the first surface facing the package substrate, wherein the pad is provided on the second surface; a top surface of a first region of the lower insulating structure is higher than that of a top surface of a second region thereof, the first region overlaps the conductive pattern, when viewed in a plan view, and the second region is exposed with respect to conductive pattern.

In some embodiments, the upper insulating structure may include an inorganic insulating layer covering the lower insulating structure and the conductive pattern and including a silicon-containing material, and a second polymer layer on the inorganic insulating layer.

In some embodiments, the inorganic insulating layer may be provided to cover and contact the top surface of the second region.

In some embodiments, the semiconductor device may further include an integrated circuit electrically connected to the pad, and the integrated circuit may be electrically connected to the package substrate through the pad, the conductive pattern, and the wire.

In some embodiments, the semiconductor chip may be part of a plurality of semiconductor chips, which are sequentially stacked on the package substrate, and each of which is electrically connected to the package substrate through the bonding pad portion and the wire.

In some embodiments, the semiconductor device may further include a barrier pattern interposed between the lower insulating structure and the conductive pattern. The conductive pattern may include an aluminum-containing material, and the barrier pattern may include Ti, TiN, or a combination thereof.

In some embodiments, the lower inorganic insulating layers may include a first lower insulating layer adjacent to the pad, a second lower insulating layer adjacent to the first polymer layer, and a third lower insulating layer interposed between the first and second lower insulating layers.

According to some embodiments of the inventive concept, a method of fabricating a semiconductor device may include forming a pad on a semiconductor chip substrate, the pad being electrically connected to an integrated circuit, forming a lower insulating layer on the substrate to cover the pad, forming a first polymer layer on the lower insulating layers to define a contact hole, patterning the lower insulating layers using the first polymer layer as an etch mask to form the contact hole exposing the pad, forming a conductive layer on the first polymer layer to fill the contact hole, and patterning the conductive layer to form a conductive pattern extending in a specific direction on the first polymer layer.

In some embodiments, the conductive pattern may include a bonding pad portion. The method may further include forming an upper insulating structure on the conductive pattern, the upper insulating structure including an upper insulating layer covering the conductive pattern and a second polymer layer on the upper insulating layer, and patterning the upper insulating structure to form an opening exposing the bonding pad portion.

In some embodiments, the forming of the conductive layer may be performed using a physical vapor deposition (PVD) process, the conductive layer in the contact hole may have a first thickness at a horizontal portion in a direction perpendicular to a top surface of the substrate and a second thickness at a vertical portion in a direction parallel to the top surface of the substrate, and the first thickness may be greater than the second thickness.

In some embodiments, the patterning of the conductive layer may include forming a recess region in the first polymer layer, and when viewed in a plan view, the recess region may be formed to not overlap with the conductive pattern.

In some embodiments, the conductive layer may include an aluminum-containing material, and the pattering of the conductive layer may include forming a photoresist pattern on the conductive layer, and performing a dry etching process on the conductive layer using the photoresist pattern as an etch mask.

According to some embodiments, a method of fabricating a semiconductor device includes: providing an integrated circuit on a semiconductor chip substrate; providing a first conductive pad on the substrate, the conductive pad electrically connected to the integrated circuit; forming an inorganic insulating layer on the substrate to cover the first conductive pad; forming an organic insulating layer on the inorganic insulating layer; removing a portion of the inorganic insulating layer above the first conductive pad, using the organic insulating layer as a mask, thereby forming an opening in the inorganic insulating layer; depositing an aluminum-containing conductive layer on the organic insulating layer, such that organic insulating layer is between the inorganic insulating layer and the aluminum-containing conductive layer, and such that the aluminum-containing conductive layer fills at least part of the opening and is connected to the first conductive pad; and patterning the aluminum-containing conductive layer to form a conductive pattern.

The aluminum-containing conductive layer may form a second conductive pad, such that the conductive pattern connects the first conductive pad to the second conductive pad.

The conductive pattern may forms a redistribution line extending from a center region of the semiconductor chip substrate to a peripheral region of the semiconductor chip substrate, wherein: the first conductive pad is in the center region of the semiconductor chip substrate; and the second conductive pad is in the peripheral region of the semiconductor chip substrate.

The method may further include forming a sidewall of the organic insulating layer during patterning the aluminum-containing conductive layer, the sidewall being coplanar with a sidewall of the conductive pattern. The sidewall of the organic insulating layer may be a sidewall of a recess in the organic insulating layer.

In certain embodiments, the organic insulating layer is a polymer layer, and the inorganic insulating layer includes a plurality of layers and includes silicon.

In certain embodiments, the method includes depositing the aluminum-containing conductive layer using a physical vapor deposition process.

In certain embodiments, removing a portion of the inorganic insulating layer above the first conductive pad includes etching the portion of the inorganic insulating layer using the organic insulating layer as a mask.

According to certain embodiments, a method of fabricating a semiconductor device includes: providing an integrated circuit on a semiconductor chip substrate; providing a first conductive pad on the substrate, the first conductive pad electrically connected to the integrated circuit chip; forming a first insulating layer on the substrate to cover the first conductive pad; forming a mask pattern on the first insulating layer, the mask pattern including an opening vertically overlapping the first conductive pad; removing a portion of the first insulating layer above the first conductive pad by performing etching using the mask pattern, thereby forming an opening in the first insulating layer; depositing an aluminum-containing conductive layer on the mask pattern, such that the mask pattern is between the first insulating layer and the aluminum-containing conductive layer, and such that the aluminum-containing conductive layer fills at least part of the opening and is connected to the first conductive pad; and patterning the aluminum-containing conductive layer to form a conductive pattern.

The first insulating layer is an inorganic insulating layer including a plurality of layers.

The conductive pattern may form a second conductive pad, such that the conductive pattern connects the first conductive pad to the second conductive pad.

The conductive pattern may form a redistribution line extending from a center region of the semiconductor chip substrate to a peripheral region of the semiconductor chip substrate. The first conductive pad may be in the center region of the semiconductor chip substrate, and the second conductive pad may be in the peripheral region of the semiconductor chip substrate.

In some embodiments, the method includes removing part of the mask pattern after depositing the aluminum-containing conductive layer.

According to some embodiments, removing part of the mask pattern includes forming a sidewall in the mask pattern. Forming the sidewall in the mask pattern may occur during a process of patterning the aluminum-containing conductive layer, such that the sidewall is coplanar with a sidewall of the conductive pattern. In some embodiments, the sidewall of the mask pattern may be a sidewall of a recess in the mask pattern.

According to some embodiments, the mask pattern is formed from an organic insulating layer formed of a polymer, and the first insulating layer is an inorganic insulating layer that includes silicon.

In some embodiments, the method includes depositing the aluminum-containing conductive layer using a physical vapor deposition process.

According to some embodiments, a method of fabricating a semiconductor device includes providing an integrated circuit on a semiconductor chip substrate; providing a first conductive pad on the substrate, the first conductive pad electrically connected to the integrated circuit; forming a first insulating layer on the substrate to cover the first conductive pad; forming a second insulating layer on the first insulating layer, the second insulating layer including an opening vertically overlapping the first conductive pad; removing a portion of the first insulating layer above the first conductive pad by using the second insulating layer as a mask pattern, thereby forming an opening in the first insulating layer; depositing a conductive layer on the second insulating layer, such that second insulating layer is between the first insulating layer and the conductive layer, and such that the conductive layer fills at least part of the opening and is connected to the first conductive pad; and patterning the conductive layer to form a conductive pattern. Patterning the conductive layer may include removing a portion of the second insulating layer to form a sidewall, at the same time as forming a sidewall of the conductive pattern, wherein the sidewall of the second insulating layer is coplanar with the sidewall of the conductive pattern. The sidewall of the second insulating layer may be part of a recess in the second insulating layer.

In some embodiments, the conductive layer is an aluminum-containing conductive layer.

In some embodiments, the first insulating layer is an inorganic insulating layer, and the second insulating layer is an organic insulating layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor package according to some embodiments of the inventive concept.

FIG. 2 is a plan view schematically illustrating a second surface of a first semiconductor chip according to some embodiments of the inventive concept.

FIG. 3 is a sectional view of sections, which are respectively taken along lines I-I′ and II-II′ of FIG. 2, and illustrates a first semiconductor chip according to some embodiments of the inventive concept.

FIG. 4A is an enlarged sectional view of a region M of FIG. 3.

FIG. 4B is an enlarged sectional view of a region N of FIG. 3.

FIGS. 5 to 9 are sectional views taken along lines I-I′ and II-II′ of FIG. 2 to illustrate a method of fabricating a first semiconductor chip, according to some embodiments of the inventive concept.

FIG. 10 is a sectional view of sections, which are respectively taken along lines I-I′ and II-II′ of FIG. 2, and illustrates a first semiconductor chip according to some embodiments of the inventive concept.

FIG. 11 is a sectional view of sections, which are respectively taken along lines I-I′ and II-II′ of FIG. 2, and illustrates a first semiconductor chip according to some embodiments of the inventive concept.

FIG. 12 is a sectional view of sections, which are respectively taken along lines I-I′ and of FIG. 2, and illustrates a first semiconductor chip according to some embodiments of the inventive concept.

FIG. 13 is a sectional view illustrating a semiconductor package according to some embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

### DETAILED DESCRIPTION

Various aspects of the inventive concepts will now be described more fully hereinafter with reference to the accompanying drawings, in which exemplary embodiments of the inventive concepts are shown. The inventive concepts and methods of achieving them will be apparent from the following exemplary embodiments that will be described in more detail with reference to the accompanying drawings. The embodiments of the inventive concept may, however, be embodied in different forms and should not be constructed as limited to the embodiments set forth herein.

As used herein, the singular terms “a,” “an” and “the” are intended to include the plural forms as well, unless the context clearly indicates otherwise. As used herein, the term “and/or” includes any and all combinations of one or more of the associated listed items and may be abbreviated as “/”. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. Similarly, the term “contacts” “contacting” or “in contact with” referring to two components mean a direct connection (i.e., touching). Additionally, the embodiments in the detailed description will be described with sectional views as ideal exemplary views of the inventive concepts. Accordingly, shapes of the exemplary views may be modified according to manufacturing techniques and/or allowable errors. The embodiments of the inventive concepts are not limited to the specific shape illustrated in the exemplary views, but may include other shapes that may be created according to manufacturing processes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Also these spatially relative terms such as “above” and “below” as used herein have their ordinary broad meanings—for example element A can be above element B even if when looking down on the two elements there is no overlap between them (just as something in the sky is generally above something on the ground, even if it is not directly above).

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Exemplary embodiments of aspects of the present inventive concepts explained and illustrated herein include their complementary counterparts. The same reference numerals or the same reference designators denote the same elements throughout the specification.

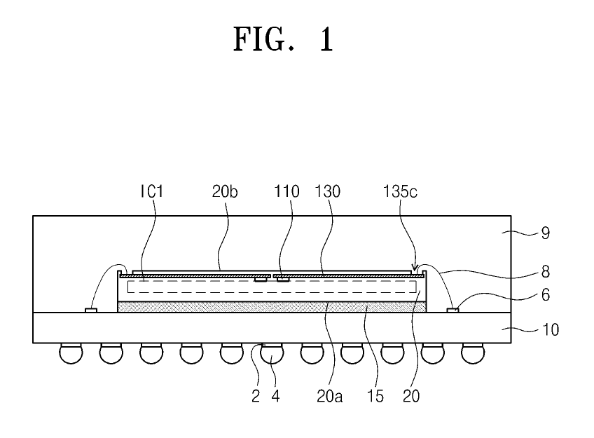

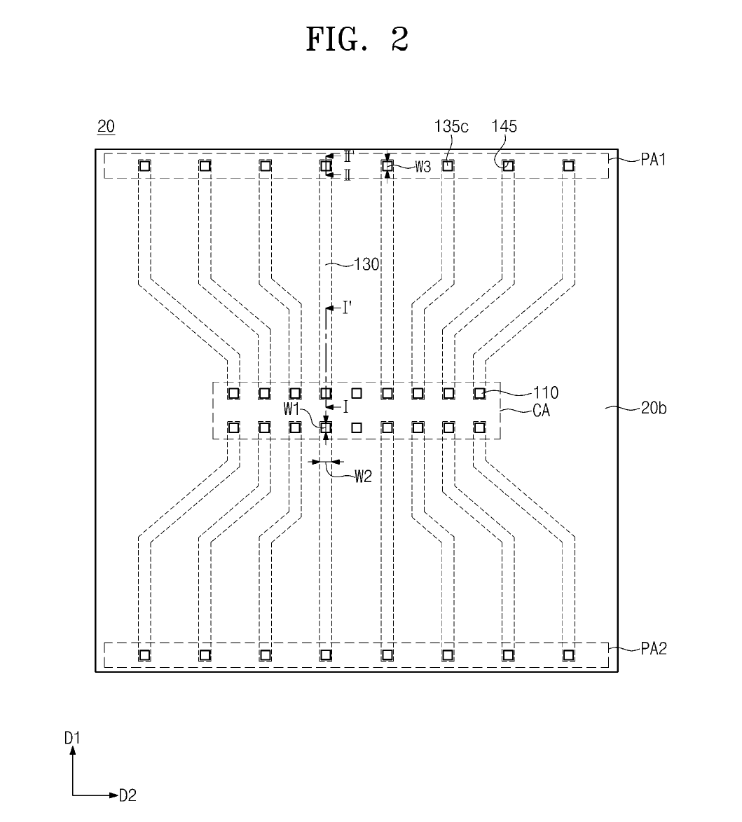

FIG. 1 is a sectional view illustrating a semiconductor package according to some embodiments of the inventive concept. FIG. 2 is a plan view schematically illustrating a second surface of a first semiconductor chip according to some embodiments of the inventive concept.

As used herein, the term “semiconductor device” may be used to describe a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as described herein, may refer to these semiconductor devices, but may additionally include products that include these devices, such as a memory module, memory card, hard drive including additional components, or a mobile phone, laptop, tablet, desktop, camera, or other consumer electronic device, etc.

Referring to FIGS. 1 and 2, a first semiconductor chip 20 may be mounted on a package substrate 10. As an example, the package substrate 10 may be a printed circuit board (PCB). The package substrate 10 may include circuit patterns (not shown) provided on one or both of top and bottom surfaces thereof. At least one of the circuit patterns may be electrically connected to first outer pads 2, which may be provided on the bottom surface of the package substrate 10. Outer pads 2 may also be referred to as external pads 2, as they are positioned and connected to transmit signals to and from an external device external to the package. In general, the pads described herein may be referred to as conductive pads. The conductive pads may be formed of a conductive material (e.g., a metal). Outer terminals 4 (e.g., solder bumps or solder balls) may be respectively attached on the first outer pads 2 to electrically connect the package substrate 10 to an external device. It should be noted that the term “terminal” can be used generally to refer to a conductive component arranged to electrically connect to another component. For example, a combined outer pad 2 and outer terminal 4 may be referred to generally together as an external terminal. The term “pad” generally refers to a conductive terminal having a flat surface profile, and often formed in a layer deposition and patterning process, and which typically connects to internal circuitry (e.g., an integrated circuit) or conductive lines of substrate or semiconductor chip. At least one other of the circuit patterns may be electrically connected to second outer pads 6, which may be provided on the top surface of the package substrate 10. Second outer pads 6 may be referred to as internal pads 6 (e.g., internal pads of the package substrate 10), as they are positioned and connected to transmit signals internally within the package (e.g., between package substrate 10 and first semiconductor chip 20).

The first semiconductor chip 20 may have a first surface 20a facing the package substrate 10 and a second surface 20b opposite the first surface 20a. The first semiconductor chip 20 may include a center area CA, or center region, and first and second peripheral areas PA1 and PA2, or peripheral regions. These areas or regions may correspond to center and peripheral areas or regions of a semiconductor chip substrate that forms the semiconductor chip. The center area CA may be positioned at a region including a center of the second surface 20b of the first semiconductor chip 20. The first and second peripheral areas PA1 and PA2 may be positioned adjacent to opposite sidewalls, respectively, of the first semiconductor chip 20. The center area CA may be disposed between the first and second peripheral areas PA1 and PA2. It should be noted that other arrangements may be used. For example, in addition to first and second peripheral areas PA1 and PA2, additional third and/or fourth peripheral areas adjacent to other sidewalls of the first semiconductor chip 20 may be included. An another example, rather than a rectangular-shaped center area having pads arranged in a two rows and a rectangular shape, other configurations, such as more than two rows and/or a square shape or less elongated rectangular shape may be formed.

The first semiconductor chip 20 may include a first integrated circuit IC1, pads 110, and redistribution layers 130. The first integrated circuit IC1 may be provided in a portion of the first semiconductor chip 20 positioned adjacent to the second surface 20b. The pads 110 may be electrically connected to the first integrated circuit IC1. When viewed in a plan view, the pads 110 may be disposed on the center area CA. The pads 110 may therefore be referred to as central pads 110.

The redistribution layers 130 may be disposed on the pads 110 (e.g., above the pads 110 such that the pads 110 are vertically between the first integrated circuit IC1 and the redistribution layers 130). The redistribution layers 130 may include bonding pad portions 135c. The bonding pad portions 135c may be electrically connected to the first integrated circuit IC1 via the pads 110. The bonding pad portions 135c may be provided on the first and second peripheral areas PA1 and PA2. The bonding pad portions 135c may be exposed to the outside of the first semiconductor chip 20. The redistribution layers 130 may be configured to allow signals from the first and second peripheral areas PA1 and PA2 to be applied to the pads 110 of the center area CA through the bonding pad portions 135c. The bonding pad portions 135c may function as bonding pads, and may be referred to herein as bonding pads when being described in connection with other adjacent conductive components.

The disclosed embodiments are not limited to the illustrated example of the pads 110 and the redistribution layers 130, and embodiments of the inventive concept may be variously changed in consideration of a type or use of a semiconductor package.

The first semiconductor chip 20 may be one of memory chips (e.g., DRAM chips or FLASH memory chips). For example, it may be a top chip or other chip in a stack of chips stacked on the package substrate 10. The first integrated circuit IC1 may include memory cells for storing data and a control and/or power circuit for controlling operations of the memory cells.

The first semiconductor chip 20 may be attached to the package substrate 10 using a first adhesive layer 15. The first adhesive layer 15 may be an insulating layer or tape (e.g., containing an epoxy or silicone-based material).

Wires 8 may be provided to electrically connect the bonding pad portions 135c of the first semiconductor chip 20 to the second outer pads 6 of the package substrate 10, respectively. The first semiconductor chip 20 may communicate with an external controller (not shown) through the wires 8. The wires 8 may be used to transmit various data, such as control signals containing address and command data, voltage signals, and any other data, to the first semiconductor chip 20 from the controller. Also, the wires 8 may be used to transmit data, which are read out from the memory cells of the first semiconductor chip 20, to the controller.

A mold layer 9 may be provided on the package substrate 10 to cover the first semiconductor chip 20 and the wires 8. The mold layer 9 may be configured to protect the first semiconductor chip 20 and the wires 8 against external environment. The mold layer 9 may include, for example, an epoxy molding compound material.

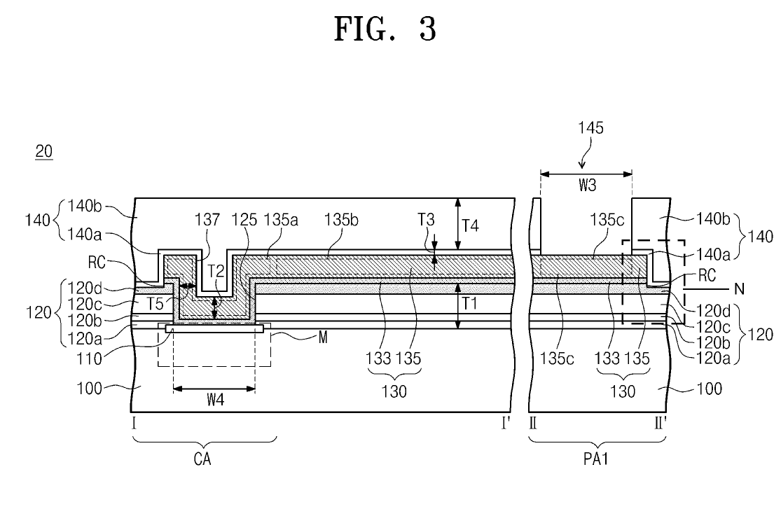

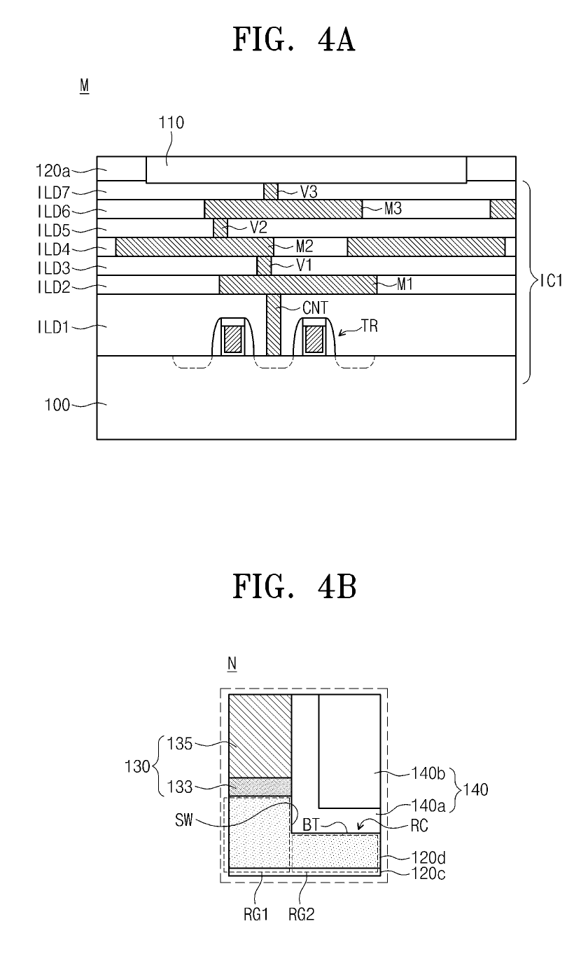

FIG. 3 is a sectional view of sections, which are respectively taken along lines I-I′ and of FIG. 2, and illustrates a first semiconductor chip according to some embodiments of the inventive concept. FIG. 4A is an enlarged sectional view of a region M of FIG. 3. FIG. 4B is an enlarged sectional view of a region N of FIG. 3. In the following description, the first semiconductor chip 20 will be described in more detail, without repeating an overlapping description of the semiconductor package previously described with reference to FIGS. 1 and 2.

Referring to FIGS. 2, 3, 4A, and 4B, the pads 110 may be provided on a center area CA of a semiconductor substrate 100. The semiconductor substrate 100, also referred to herein as a semiconductor chip substrate, may be a silicon wafer, a germanium wafer, or a silicon-germanium wafer. The pads 110 may be arranged to form two columns within the center area CA, but the inventive concept is not limited thereto. The pads 110 may be formed of or include a conductive material (e.g., aluminum (Al)). At least one of the pads 110 may have a first width W1, when measured in a first direction D1 parallel to a top surface of the semiconductor substrate 100. In some embodiments, the first width W1 may be an amount in the range from 5 μm to 50 μm. Hereinafter, one of the pads 110 will be exemplarily described, for concise description.

The pad 110 may be electrically connected to the first integrated circuit IC1 in the first semiconductor chip 20. Referring back to FIG. 4A, the first integrated circuit IC1 may be disposed on the semiconductor substrate 100. The first integrated circuit IC1 may include a plurality of transistors TR, a plurality of metal layers M1-M3, and a plurality of vias V1-V3.

Each of the transistors TR may include a gate electrode and impurity regions provided at both side of the gate electrode. The impurity regions may be doped regions, which may be formed by injecting impurities into the semiconductor substrate 100. Each of the transistors TR may be used as a part of the memory cells or as a part of the control and/or power circuit for controlling operations of the memory cells.

First to seventh interlayered insulating layers ILD1-ILD7 may be sequentially stacked on the semiconductor substrate 100. The first interlayered insulating layer ILD1 may be provided to cover the transistors TR. A contact CNT (e.g., a through-via) may be provided to pass through the first interlayered insulating layer ILD1 and may be connected to one of the impurity regions of the transistors TR.

A first metal layer M1, a second metal layer M2, and a third metal layer M3 may be provided in the second interlayered insulating layer ILD2, the fourth interlayered insulating layer ILD4, and the sixth interlayered insulating layer ILD6, respectively. The pad 110 may be provided on the seventh interlayered insulating layer ILD7. A first via V1 may be provided between the first and second metal layers M1 and M2, a second via V2 may be provided between the second and third metal layers M2 and M3, and a third via V3 may be provided between the third metal layer M3 and the pad 110. The pad 110 may be electrically connected to the transistors TR through the metal layers M1-M3 and the vias V1-V3.

Referring back to FIGS. 2 and 3, a lower insulating structure 120 may be disposed on a top surface of the semiconductor substrate 100. The lower insulating structure 120 may be disposed to partially cover the pad 110. The lower insulating structure 120 may have a first thickness T1. As an example, the first thickness T1 may be an amount in the range from 0.1 μm to 3 μm.

A contact hole 125 may be provided to penetrate the lower insulating structure 120 and expose the remaining portion of the pad 110, in relation to the lower insulating structure 120. The contact hole 125 may have a fourth width W4, when measured in the first direction D1. The fourth width W4 may be smaller than the first width W1. For example, the fourth width W4 may be an amount in the range from 5 μm to 50 μm.

The lower insulating structure 120 may include first to third lower insulating layers 120a, 120b, and 120c and a first polymer layer 120d, which are sequentially stacked on the semiconductor substrate 100. For example, the second lower insulating layer 120b may be interposed between the first and third lower insulating layers 120a and 120c. The first to third lower insulating layers 120a, 120b, and 120c may be referred to herein collectively as a lower insulating layer. Also, the different insulating layers described herein may be referred to as first, second, third, etc., insulating layers, as a way of naming the different layers. Thus, the lower insulating layer (e.g., including first to third lower insulating layers 120a, 120b, and 120c) may be referred to as a first insulating layer. The first polymer layer (e.g., 120d) may also be referred to as an insulating layer (e.g., a “first” insulating layer or a “second” insulating layer). The first polymer layer 120d may be provided to cover a top surface of the third lower insulating layer 120c. Here, the third lower insulating layer 120c may have a thickness greater than that of the first lower insulating layer 120a and/or that of the second lower insulating layer 120b.

Each of the first to third lower insulating layers 120a, 120b, and 120c may be formed of or include an inorganic insulating layer (e.g., of silicon nitride, silicon oxide, or silicon oxynitride). As an example, each of the first and third lower insulating layers 120a and 120c may include a silicon oxide layer, and the second lower insulating layer 120b may include a silicon nitride layer. Here, the first semiconductor chip 20 may be a DRAM chip.

The first polymer layer 120d may be provided to define a recess region RC. When viewed in a plan view, for example, a recess region RC included in the first polymer layer 120d may be spaced apart from the redistribution layer 130. For example, the recess region RC may not overlap the redistribution layer 130, when viewed in a plan view.

Referring back to FIG. 4B, the recess region RC may have a bottom surface BT, which is positioned at a lower level than that of the top surface of the first polymer layer 120d provided under the redistribution layer 130. An upper insulating layer 140a may be provided to directly cover a sidewall SW and the bottom surface BT of the recess region RC.

For example, the lower insulating structure 120 may include a first region RG1 and a second region RG2. When viewed in a plan view, the first region RG1 may overlap the redistribution layer 130, and the second region RG2 may overlap the recess region RC. Here, a top surface of the first region RG1 may be higher than a top surface of the second region RG2 (e.g., the bottom surface BT of the recess region RC).

The first polymer layer 120d may include a polymeric material, which can be used as an organic photoresist layer. As such, it may be referred to as an organic insulating layer. For example, the polymer material may be formed of or include poly(4-hydroxystyrene) (PHS) or polyimide, but the inventive concept is not limited thereto. The polymer material may be selected to have a dielectric constant having a value ranging from about 2.5 to about 3.5. The dielectric constant of the polymer material may be lower than that of the inorganic insulating layer (e.g., the lower insulating layers 120a, 120b, and 120c). Even if, in order to realize an electric isolation of the redistribution layer 130, the thickness T1 of the lower insulating structure 120 becomes sufficiently large, the use of the first polymer layer 120d may make it possible to reduce an effective dielectric constant of the lower insulating structure 120. Accordingly, it is possible to suppress the redistribution layer 130 from being capacitively coupled with the metal layers M1-M3.

The redistribution layer 130 may be provided on the lower insulating structure 120 to fill at least a portion of the contact hole 125 and be electrically connected to the pad 110. In some embodiments, as shown in FIG. 2, a plurality of redistribution layers 130 may be provided on the lower insulating structure 120. When viewed in a plan view, each of the redistribution layers 130 may be a line-shaped structure extending from the pads 110 toward the first direction D1. Some of the redistribution layers 130 may extend in opposite directions from each other. For example, the redistribution layers 130 may extend from the center area CA to the first peripheral area PA1 or from the center area CA to the second peripheral area PA2. At least one of the redistribution layers 130 may include a portion extending in a direction other than the first direction D1 (e.g., a diagonal direction or a direction crossing the first direction D1). In some embodiments, the redistribution layers 130 may be disposed to have end portions that are uniformly arranged on the first and second peripheral areas PA1 and PA2. The redistribution layers, also referred to individually as redistribution lines, each include at least a first conductive pattern (e.g., 135) arranged to electrically connect between a first pad (e.g., a pad such as a pad 110 at the center area CA) and a second area (e.g., a peripheral area PA1 or PA2).

At least one of patterns constituting the redistribution layer 130 may have a second width W2, when measured in a second direction D2 crossing the first direction D1. The second direction D2 may be selected to be parallel to the top surface of the semiconductor substrate 100. As an example, each of the redistribution layers 130 may serve as a signal line, a power line, or a ground line. In some embodiments, a width of each of the redistribution layers 130 may be dependent on its assigned function. For example, the second width W2 may be an amount in the range from 2 μm to 200 μm.

The redistribution layer 130 may include a barrier pattern 133 and a conductive pattern 135 on the barrier pattern 133. The barrier pattern 133 may be interposed between the lower insulating structure 120 and the conductive pattern 135. The barrier pattern 133 may overlap the conductive pattern 135, when viewed in a plan view. The conductive pattern 135 and the barrier pattern 133 may have sidewalls that are vertically aligned with each other.

The barrier pattern 133 may be provided to prevent metallic elements from being diffused from the conductive pattern 135 to the lower insulating structure 120, and for example, may be formed of or include at least one of Ti or TiN. In addition, the barrier pattern 133 may be configured to have a good wetting property with respect to the lower insulating structure 120 thereunder. In some embodiments, the term “redistribution layer” may refer to only the conductive pattern 135, or the combined patterned conductive layers 133 and 135 may be referred to as a conductive pattern. The barrier pattern 133 may be referred to as a first conductive layer pattern, and the conductive pattern 135 may be referred to as a second conductive layer pattern.

The conductive pattern 135 may include a contact portion 135a filling the contact hole 125, a conductive line portion 135b extending in the first direction D1 on the lower insulating structure 120, and a bonding pad portion 135c. The contact portion 135a, the conductive line portion 135b, and the bonding pad portion 135c may be connected to form a single body (e.g., the conductive pattern 135). For example, the contact portion 135a, the conductive line portion 135b, and the bonding pad portion 135c may be a continuous structure formed without spaces or boundaries therebetween.

The contact portion 135a may have a second thickness T2, when measured in a direction perpendicular to the top surface of the semiconductor substrate 100 (e.g., for horizontally-oriented portions). In addition, the contact portion 135a in the contact hole 125 may have a fifth thickness T5, when measured in the first direction D1 or the second direction D2 (e.g., for vertically-oriented portions). In some embodiments, the second thickness T2 may be greater than the fifth thickness T5. For example, the second thickness T2 may range from 1 μm to 8 μm. The contact portion 135a filling the contact hole 125 may be provided to define a depressed region 137.

The conductive line portion 135b may be positioned between the contact portion 135a and the bonding pad portion 135c. Similar to the redistribution layers 130 previously described with reference to FIG. 2, the conductive line portion 135b may be a line-shaped structure extending in the first direction D1. The line-shaped structures may have bent portions such as shown in FIG. 2, for example, wherein certain portions of each line extend in the first direction D1 and other portions of each line extend in a different (e.g., angled) direction. The conductive line portion 135b may be provided to allow the bonding pad portion 135c on the first peripheral area PA1 to be electrically connected to the contact portion 135a on the center area CA.

The conductive pattern 135 may include a metallic material, on which a deposition and patterning process can be effectively performed. As an example, the conductive pattern 135 may be formed of or include aluminum (Al).

An upper insulating structure 140 may be provided on the redistribution layer 130 and the lower insulating structure 120. The upper insulating structure 140 may include an upper insulating layer 140a and a second polymer layer 140b, which may be sequentially stacked on the semiconductor substrate 100. The upper insulating layer 140a may be provided to directly cover the redistribution layer 130. For example, the upper insulating layer 140a may directly cover, and may contact, top and side surfaces of the conductive pattern 135 and a side surface of the barrier pattern 133. The first upper insulating layer 140a may be conformally formed on the redistribution layer 130, other than a portion where it is removed (e.g., on the bonding pad portion 135c of the redistribution layer 130). As shown in FIG. 4B, the upper insulating layer 140a may directly cover, and may contact, the recess region RC of the first polymer layer 120d. Thus, the upper insulating layer 140a may directly cover the sidewall SW and the bottom surface BT of the recess region RC. As shown in FIGS. 3 and 4B, the upper insulating layer 140a may contact both a lower top surface of the first polymer layer 120d and a side surface of the first polymer layer 120d. In addition, the upper insulating layer 140a may contact a side surface of the barrier pattern 133 and a side surface conductive pattern 135, which are coplanar with the side surface of the first polymer layer 120d.

The second polymer layer 140b may be spaced apart from the redistribution layer 130 with the upper insulating layer 140a interposed therebetween. The upper insulating structure 140 may be provided to protect the redistribution layer 130 against external environment and to prevent a short circuit from being formed between the redistribution layers 130.

A first opening 145 may be provided to penetrate the first upper insulating structure 140 and to expose the bonding pad portion 135c. For example, as shown in FIG. 2, a plurality of first openings 145 may be provided on the first and second peripheral areas PA1 and PA2 to expose the bonding pad portions 135c, respectively.

The first opening 145 may have the third width W3 in the first direction D1. The third width W3 may be greater than the fourth width W4. In some embodiments, the third width W3 may be a width sufficient to allow the wire bonding process to be easily performed on the bonding pad portion 135c. For example, the third width W3 may be an amount in the range from 100 μm to 300 μm.

In some embodiments, the upper insulating layer 140a may include a silicon-containing inorganic insulating layer (e.g., a silicon nitride layer, a silicon oxide layer, or a silicon oxynitride layer). By contrast, the second polymer layer 140b may be formed of or include an organic insulating layer (e.g., at least one of polyimide, fluoro carbon, resin, or synthetic rubber). The upper insulating layer 140a may have a third thickness T3, and the second polymer layer 140b may have a fourth thickness T4. Here, the fourth thickness T4 may be greater than the third thickness T3, for example, when measured in the same vertical direction at a particular horizontal location. As an example, the third thickness T3 may be an amount in the range from 0.1 μm to 3 μm and the fourth thickness T4 may be an amount in the range from 0.3 μm to 6 μm.

FIGS. 5 to 9 are sectional views taken along lines I-I′ and II-II′ of FIG. 2 to illustrate a method of fabricating a first semiconductor chip, according to some embodiments of the inventive concept.

Referring to FIGS. 2 and 5, a first integrated circuit IC1 may be formed on a semiconductor substrate 100. The formation of the first integrated circuit IC1 may include forming a plurality of transistors TR, a plurality of metal layers M1-M3, and a plurality of vias V1-V3 and may be performed using the same method as described with reference to FIG. 4A.

Pads 110 may be formed on the center area CA of the semiconductor substrate 100. The pads 110 may be electrically connected to the first integrated circuit IC1. Hereinafter, one of the pads 110 will be exemplarily described, for concise description.

Lower insulating layers 120a, 120b, and 120c may be formed to cover the pad 110. For example, the formation of the lower insulating layers 120a, 120b, and 120c may include sequentially forming a first lower insulating layer 120a, a second lower insulating layer 120b, and a third lower insulating layer 120c on the top surface of the semiconductor substrate 100. The first to third lower insulating layers 120a, 120b, and 120c may be formed, for example, by an atomic layer deposition (ALD) process or a chemical vapor deposition (CVD) process. As an example, the first and third lower insulating layers 120a and 120c may be formed of or include a silicon oxide layer, and the second lower insulating layer 120b may be formed of or include a silicon nitride layer.

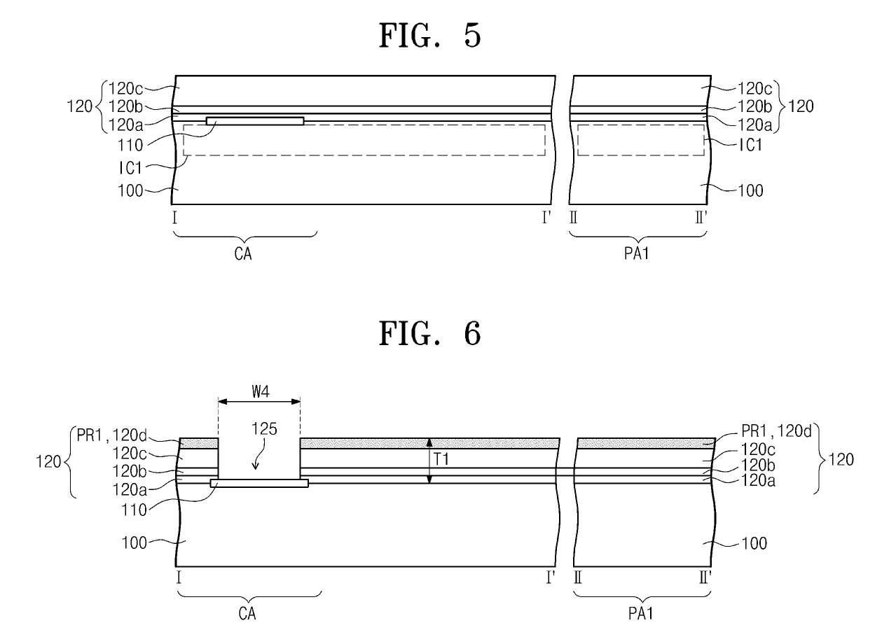

Referring to FIGS. 2 and 6, a first photoresist pattern PR1 may be formed on the lower insulating layers 120a, 120b, and 120c. The first photoresist pattern PR1 may have an opening overlapping the pad 110, when viewed in a plan view. The first photoresist pattern PR1 may be formed, for example, of an organic photoresist compound containing poly(4-hydroxystyrene) (PHS) or polyimide. The first photoresist pattern PR1 may be formed from the organic insulating layer 120d. The first photoresist pattern PR1, which may be referred to as an insulating pattern formed from an insulating layer, may also be referred to as a mask pattern. The mask pattern may have an opening that vertically overlaps the pad 110.

The lower insulating layers 120a, 120b, and 120c may be patterned using the first photoresist pattern PR1 as an etch mask, thereby forming the contact hole 125 exposing the pad 110. Though one example contact hole 125 is shown, a plurality of contact holes may be formed at the same time for a plurality of pads 110. In one embodiment, the first photoresist pattern PR1 is not removed after the formation of the contact hole 125. Accordingly, the first photoresist pattern PR1 may be used as the first polymer layer 120d according to some embodiments of the inventive concept. The lower insulating layers 120a, 120b, and 120c and the first polymer layer 120d may constitute the lower insulating structure 120.

The lower insulating structure 120 may be formed to have the first thickness Ti. As an example, the first thickness T1 may be an amount in the range from 0.1 μm to 3 μm. The contact hole 125 may be formed to have the fourth width W4. For example, the fourth width W4 may be an amount in the range from 5 μm to 50 μm.

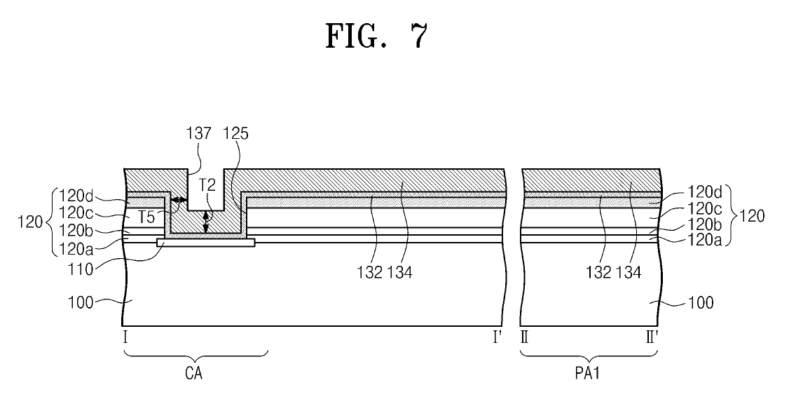

Referring to FIGS. 2 and 7, a barrier layer 132 and a conductive layer 134 may be sequentially formed on the resulting structure with the lower insulating structure 120. Each of the barrier layer 132 and the conductive layer 134 may be formed to fill at least a portion of the contact hole 125. In some embodiments, the barrier layer 132 may be formed to directly cover the pad 110 (e.g., to cover and be in contact with the pad 110), and the conductive layer 134 may be formed to partially, and not wholly, fill the contact hole 125, thereby defining a depressed region 137, also referred to herein as a recessed region. The barrier layer 132 and conductive layer 134 may together be referred to as a conductive layer.

The barrier layer 132 and the conductive layer 134 may be formed using a physical vapor deposition (PVD) process. Here, the conductive layer 134 in the contact hole 125 may be formed to have a second thickness T2 where the conductive layer 134 extends horizontally, when measured in a direction perpendicular to the top surface of the semiconductor substrate 100. The conductive layer 134 in the contact hole 125 may have a fifth thickness T5 where it extends vertically, when measured in the first direction D1 or the second direction D2. Since the conductive layer 134 is formed by a deposition method with a poor step coverage property (e.g., PVD process), the second thickness T2 may be greater than the fifth thickness T5.

In some embodiments, the barrier layer 132 may be formed of or include at least one of Ti or TiN. The conductive layer 134 may be formed of or include a metallic material (e.g., containing aluminum (Al)).

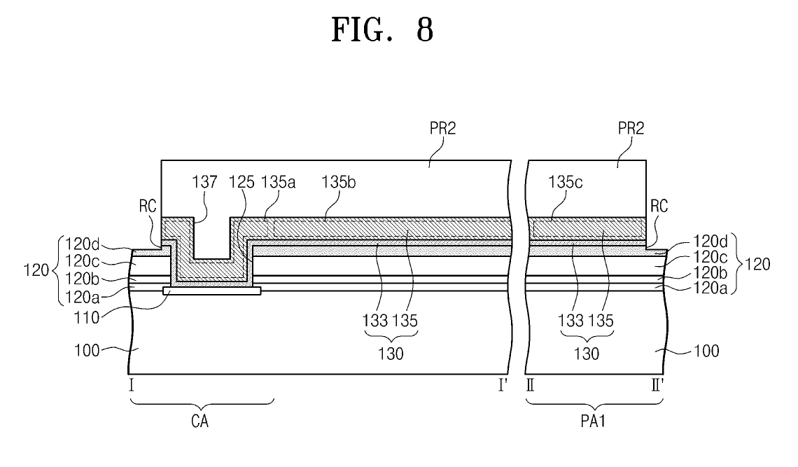

Referring to FIGS. 2 and 8, a second photoresist pattern PR2 may be formed on the conductive layer 134. In some embodiments, a plurality of second photoresist patterns PR2 may be formed to define positions and shapes of the redistribution layers 130 described with reference to FIGS. 2 and 3.

The conductive layer 134 and the barrier layer 132 may be sequentially etched using the second photoresist pattern PR2 as an etch mask to form the redistribution layer 130. The etching process of the conductive layer 134 and the barrier layer 132 may be performed using a dry etching process. As an example, an etching gas containing BCl₃ and/or SF₆ may be used for the dry etching process, but the inventive concept not limited thereto. The redistribution layer 130 may include a barrier pattern 133 and a conductive pattern 135 on the barrier pattern 133. The conductive pattern 135 may include a contact portion 135a, a conductive line portion 135b, and a bonding pad portion 135c.

In one embodiment, the second photoresist pattern PR2 is used as a common mask for forming the conductive pattern 135 and the barrier pattern 133, so that the conductive pattern 135 and the barrier pattern 133 may overlap each other, when viewed in a plan view. Accordingly, the conductive pattern 135 and the barrier pattern 133 may be formed to have sidewalls aligned with each other in plan view (e.g., coplanar sidewalls or side surfaces).

An upper portion of the lower insulating structure 120 may be etched during the process of etching the conductive layer 134 and the barrier layer 132. For example, during the etching process, the conductive layer 134 and the barrier layer 132 exposed by the second photoresist pattern PR2 may be removed, and then, a portion of the first polymer layer 120d thereunder may be partially etched. As a result, during the process of etching the redistribution layer 130, a recess region RC may be formed in the first polymer layer 120d (e.g., in the mask pattern used previously for forming the contact hole 125. Here, the recess region RC may be formed to have a bottom surface that is lower than the top surface of the first polymer layer 120d provided under the redistribution layer 130. The recess region RC may also have a sidewall that is coplanar with sidewalls of the conductive pattern 135 and barrier pattern 133. Thus, in some embodiments, patterning the conductive layer 134 includes removing a portion of the first polymer layer 120d to form a sidewall, at the same time as forming a sidewall of the conductive pattern 135, wherein the sidewall of the first polymer layer 120d (also referred to generally herein as an organic insulating layer, second insulating layer, or mask pattern) is coplanar with the sidewall of the conductive pattern 135.

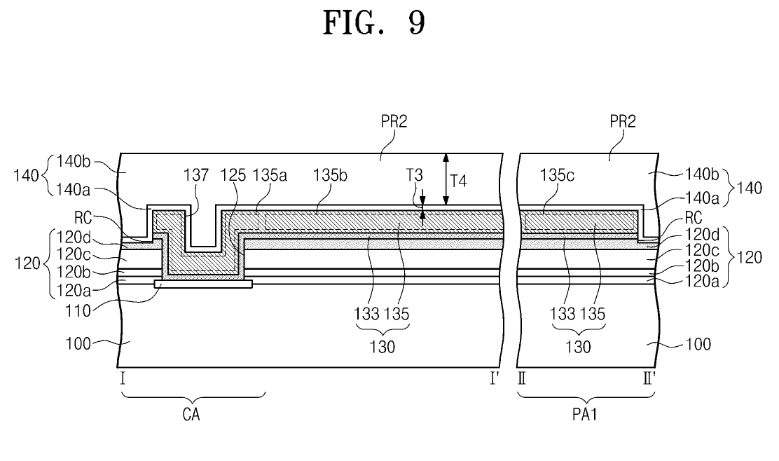

Referring to FIGS. 2 and 9, a remaining portion of the second photoresist pattern PR may be selectively removed. Thereafter, an upper insulating structure 140 may be formed on the redistribution layer 130 and the lower insulating structure 120.

For example, the formation of the upper insulating structure 140 may include sequentially forming an upper insulating layer 140a and a second polymer layer 140b on the semiconductor substrate 100. The upper insulating layer 140a may be formed, for example, by an atomic layer deposition (ALD) process or a chemical vapor deposition (CVD) process. The second polymer layer 140b may be formed by coating a polymer material (e.g., at least one of polyimide, fluoro carbon, resin, or synthetic rubber) or a precursor thereof on the upper insulating layer 140a. The upper insulating layer 140a may be formed to have a third thickness T3, and the second polymer layer 140b may be formed to have a fourth thickness T4. Here, the fourth thickness T4 (e.g., in a vertical direction) may be greater than the third thickness T3 (e.g., in a vertical direction).

Referring to FIGS. 2 and 3, the upper insulating structure 140 may be patterned to form a first opening 145 exposing the bonding pad portion 135c. The patterning of the upper insulating structure 140 may include forming a third photoresist pattern (not shown) and etching the upper insulating structure 140 using the third photoresist pattern as an etch mask, where the third photoresist pattern is formed to define an opening overlapping the bonding pad portion 135c. The first opening 145 may be formed to have a third width W3 (e.g., in a horizontal direction D1 or D2). For example, the third width W3 may range from 100 μm to 300 μm. In a subsequent package process, a wire bonding process may be performed on the bonding pad portion 135c exposed by the first opening 145. As such, the bonding pad portion 135c may function as a bonding pad, and may be referred to herein as a bonding pad.

According to some embodiments of the inventive concept, the redistribution layer 130 may be formed of an inexpensive metal (e.g., aluminum), instead of gold or copper, and thus, it is possible to reduce production cost in a process of fabricating a semiconductor chip. In addition, the redistribution layer 130 may be formed by a deposition and patterning process on a metal such as aluminum, not by a plating process (for example, a gold or copper plating process), and thus, this may make it possible to use the existing metal patterning system for the process of forming the redistribution layer 130. In some embodiments, for example, the redistribution layer 130 includes aluminum and does not include gold or copper (e.g., it may include only aluminum). Accordingly, it is possible to improve process efficiency in the fabrication process.

In the fabrication method according to some embodiments of the inventive concept, by allowing the first photoresist pattern PR1 for patterning the lower insulating layers 120a, 120b, and 120c, to remain, it is possible to simplify the overall fabrication process and to reduce an effective dielectric constant of the lower insulating structure 120.

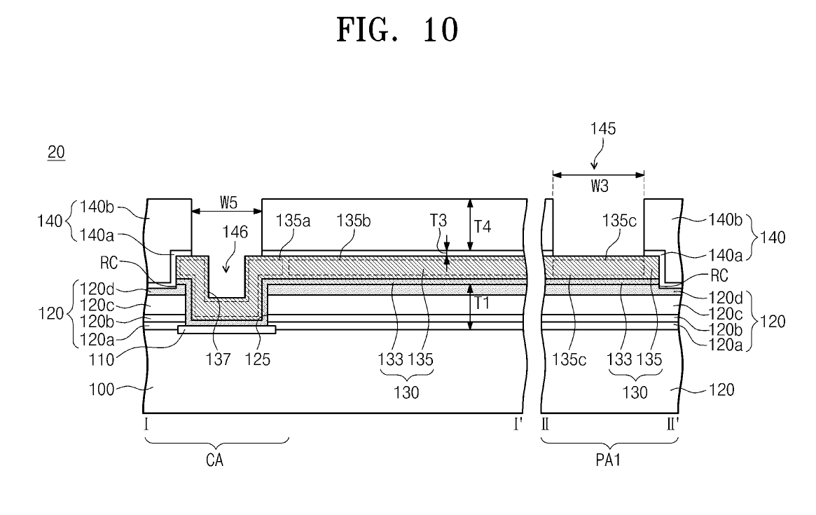

FIG. 10 is a sectional view of sections, which are respectively taken along lines and of FIG. 2, and illustrates a first semiconductor chip according to some embodiments of the inventive concept. In the following description, an element of the first semiconductor chip previously described with reference to FIGS. 2 to 4B may be identified by a similar or identical reference number without repeating an overlapping description thereof, for the sake of brevity.

Referring to FIGS. 2 and 10, a second opening 146 may be provided to penetrate the upper insulating structure 140 and expose the contact portion 135a. The second opening 146 may have the fifth width W5. In some embodiments, the fifth width W5 may be an amount in the range from 10 μm to 100 μm.

Although not shown, an additional outer terminal may be coupled to the contact portion 135a through the second opening 146. Accordingly, this structure of the contact portion 135a, in conjunction with the bonding pad portion 135c exposed by the first opening 145, may make it possible to increase a degree of freedom in establishing a routing path with an external controller (not shown).

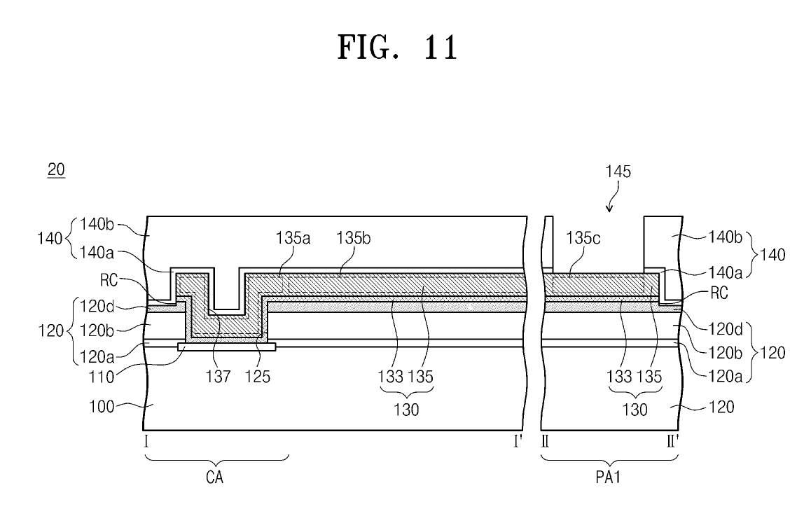

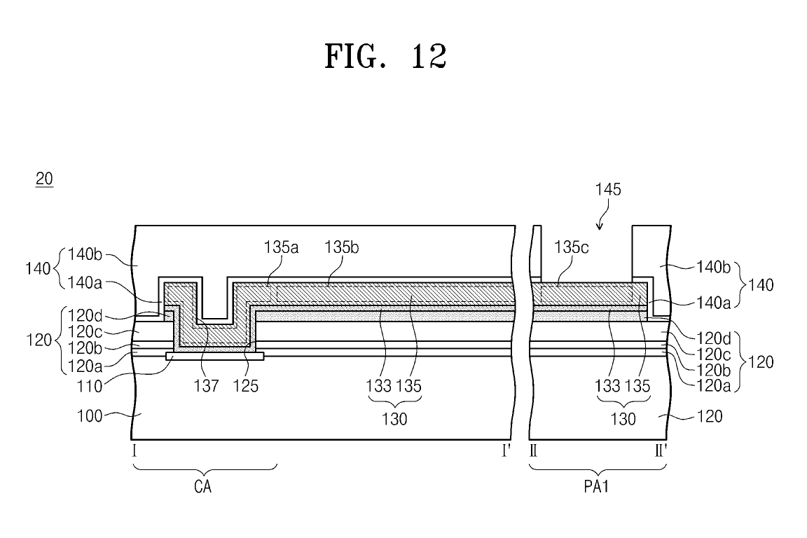

FIG. 11 is a sectional view of sections, which are respectively taken along lines and of FIG. 2, and illustrates a first semiconductor chip according to some embodiments of the inventive concept. In the following description, an element of the first semiconductor chip previously described with reference to FIGS. 2 to 4B may be identified by a similar or identical reference number without repeating an overlapping description thereof, for the sake of brevity.

Referring to FIGS. 2 and 11, the lower insulating structure 120 may include the first lower insulating layer 120a, the second lower insulating layer 120b, and the first polymer layer 120d, which are sequentially stacked on the semiconductor substrate 100. Each of the first and second lower insulating layers 120a and 120b may include an inorganic insulating layer (e.g., a silicon nitride layer, a silicon oxide layer, or a silicon oxynitride layer). For example, the first lower insulating layer 120a may be formed of or include a silicon nitride layer, and the second lower insulating layer 120b may be formed of or include a silicon oxide layer.

FIG. 12 is a sectional view of sections, which are respectively taken along lines and of FIG. 2, and illustrates a first semiconductor chip according to some embodiments of the inventive concept. In the following description, an element of the first semiconductor chip previously described with reference to FIGS. 2 to 4B may be identified by a similar or identical reference number without repeating an overlapping description thereof, for the sake of brevity.

Referring to FIGS. 2 and 12, the first polymer layer 120d may overlap the redistribution layer 130, when viewed in a plan view (e.g., they may vertically overlap each other). The first polymer layer 120d may have a sidewall aligned with that of the redistribution layer 130. For example, the first polymer layer 120d exposed by the second photoresist pattern PR2 may be completely removed during the etching process of the redistribution layer 130 previously described with reference to FIG. 8. In this example, as in the embodiments where the first polymer layer 120d includes a recess, the first polymer layer 120d includes a side surface that is coplanar with a side surface of the redistribution layer 130 (e.g., the side surfaces being at a longitudinal terminal end of the redistribution layer 130).

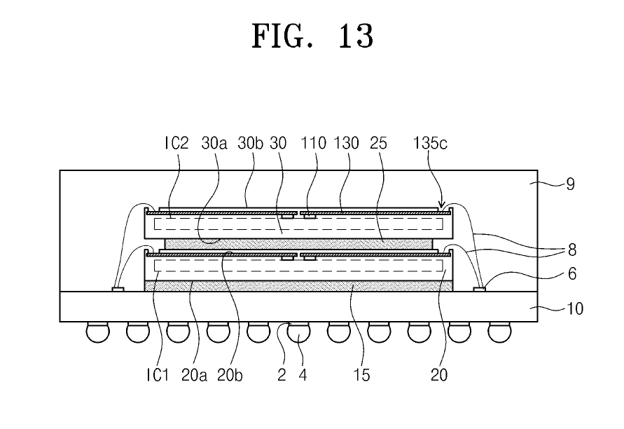

FIG. 13 is a sectional view illustrating a semiconductor package according to some embodiments of the inventive concept. In the following description, an element of the semiconductor package previously described with reference to FIGS. 1 and 2 may be identified by a similar or identical reference number without repeating an overlapping description thereof, for the sake of brevity.

Referring to FIG. 13, the first semiconductor chip 20 may be mounted on the package substrate 10, and a second semiconductor chip 30 may be mounted on the first semiconductor chip 20. The second semiconductor chip 30 may have a third surface 30a facing the first semiconductor chip 20 and a fourth surface 30b opposite to the third surface 30a.

The second semiconductor chip 30 may be a chip that is the same as or similar to the first semiconductor chip 20. For example, the second semiconductor chip 30 may be configured to have a second integrated circuit IC2, in addition to the pads 110 and the redistribution layers 130. The redistribution layers 130 may include the bonding pad portions 135c. In some embodiments, the second semiconductor chip 30 may be one of memory chips (e.g., DRAM chips or FLASH memory chips). The second integrated circuit IC2 may include memory cells for storing data and a control and/or power circuit for controlling operations of the memory cells.

The second semiconductor chip 30 may be attached to the first semiconductor chip 20 using the second adhesive layer 25. The second adhesive layer 25 may be an insulating layer or tape (e.g., containing an epoxy or silicone-based material). The second adhesive layer 25 may have a top surface positioned at a higher level than the topmost level of the wires 8 connected to the first semiconductor chip 20.

The wires 8 may be provided to respectively connect the bonding pad portions 135c of the second semiconductor chip 30 to the second outer pads 6 of the package substrate 10. The second semiconductor chip 30 may communicate with an external controller (not shown) through the wires 8.

The mold layer 9 may be provided on the package substrate 10 to cover the first and second semiconductor chips 20 and 30 and the wires 8. The mold layer 9 may be configured to protect the first and second semiconductor chips 20 and 30 and the wires 8 against external environment.

In some embodiments, the semiconductor package may further include at least one semiconductor chip disposed on the second semiconductor chip 30, in addition to the first and second semiconductor chips 20 and 30.

According to some embodiments of the inventive concept, a redistribution layer of a semiconductor chip may be formed by a deposition and patterning process, not by a plating process. This may make it possible to economically fabricate a semiconductor chip. In addition, a photoresist pattern containing an organic polymer material may be used as a lower insulating layer provided below the redistribution layer, and this may make it possible to reduce an effective capacitance of the lower insulating layer.

While example embodiments of the inventive concepts have been particularly shown and described, it will be understood by one of ordinary skill in the art that variations in form and detail may be made therein without departing from the spirit and scope of the attached claims.

1. A semiconductor device, comprising:
an integrated circuit on a semiconductor chip substrate;
a pad electrically connected to the integrated circuit;
a lower insulating structure having a contact hole exposing the pad; and
a conductive pattern comprising: a contact portion filling at least part of the contact hole, a conductive line portion provided on the lower insulating structure to extend in a specific direction, and a bonding pad portion,
wherein the contact portion has a first thickness at a horizontal portion in a direction perpendicular to a top surface of the substrate and a second thickness at a vertical portion in another direction parallel to the top surface of the substrate,
the first thickness is greater than the second thickness, and
the lower insulating structure comprises:
a plurality of lower inorganic insulating layers sequentially stacked on the substrate; and
a first polymer layer on the lower inorganic insulating layers.

2. The semiconductor device of claim 1, wherein the first polymer layer comprises poly(4-hydroxystyrene) (PHS) or polyimide.

3. The semiconductor device of claim 1, wherein the first polymer layer comprises a recess region, and
when viewed in a plan view, the recess region does not overlap the conductive pattern.

4. The semiconductor device of claim 1, wherein, when viewed in a plan view, the first polymer layer overlaps the conductive pattern, and a sidewall of the first polymer layer is aligned with that of the conductive pattern.

5. The semiconductor device of claim 1, wherein the contact portion is provided to fill at least a portion of the contact hole and define a recessed region.

6. The semiconductor chip of claim 1, wherein the pad is electrically connected to the integrated circuit thereunder through a plurality of metal layers and a plurality of vias.

7. The semiconductor device of claim 1, wherein, when viewed in a plan view, the pad is provided on a center area of the semiconductor chip substrate and the bonding pad portion is provided on a peripheral area of the semiconductor chip substrate.

8. The semiconductor device of claim 1, further comprising an upper insulating structure having a first opening exposing the bonding pad portion,
wherein the upper insulating structure comprises:
an upper insulating layer covering the lower insulating structure and the conductive pattern; and
a second polymer layer on the upper insulating layer.

9. The semiconductor device of claim 8, wherein the upper insulating layer is provided to directly cover top and side surfaces of the conductive pattern.

10-11. (canceled)

12. The semiconductor device of claim 8, wherein the upper insulating structure further comprises a second opening exposing the contact portion.

13. The semiconductor device of claim 1, wherein each of the lower inorganic insulating layers comprises a silicon nitride layer, a silicon oxide layer, or a silicon oxynitride layer.

14. The semiconductor device of claim 13, wherein the semiconductor device is a semiconductor chip.

15. (canceled)

16. The semiconductor device of claim 1, wherein the conductive pattern comprises an aluminum-containing material.

17. A semiconductor device, comprising:
an integrated circuit on a semiconductor chip substrate;
a pad electrically connected to the integrated circuit;
a lower insulating structure having a contact hole exposing the pad;
a conductive pattern comprising: a contact portion filling at least part of the contact hole, a conductive line portion provided on the lower insulating structure to extend in a specific direction, and a bonding pad portion; and
an upper insulating structure having an opening exposing the bonding pad portion,
wherein the lower insulating structure comprises:
a plurality of lower inorganic insulating layers sequentially stacked on the substrate; and
a first polymer layer on the lower inorganic insulating layers, and
the first polymer layer comprises a recess region that does not overlap the conductive pattern, when viewed in a plan view.

18. The semiconductor device of claim 17, wherein the upper insulating structure comprises:
an upper insulating layer covering the lower insulating structure and the conductive pattern; and
a second polymer layer on the upper insulating layer.

19. The semiconductor device of claim 17, wherein the upper insulating layer is provided to cover and contact side and bottom surfaces of the recess region.

20. The semiconductor device of claim 17, further comprising:
a package substrate, wherein the integrated circuit and semiconductor chip substrate form a semiconductor chip provided on the package substrate, the semiconductor chip electrically connected to the package substrate with a wire,
wherein the semiconductor chip comprises:
first and second surfaces opposite each other, the first surface facing the package substrate, wherein:
the pad is provided on the second surface;
a top surface of a first region of the lower insulating structure is higher than that of a top surface of a second region thereof,
the first region overlaps the conductive pattern, when viewed in a plan view, and
the second region is exposed with respect to conductive pattern.

21. The semiconductor device of claim 20, further comprising an upper insulating structure including:
an inorganic insulating layer covering the lower insulating structure and the conductive pattern and comprising a silicon-containing material; and
a second polymer layer on the inorganic insulating layer.

22. The semiconductor device of claim 21, wherein the inorganic insulating layer is provided to cover and contact the top surface of the second region.

23. The semiconductor device of claim 20, wherein the semiconductor chip further comprises an integrated circuit electrically connected to the pad, and
the integrated circuit is electrically connected to the package substrate through the pad, the conductive pattern, and the wire.

24-53. (canceled)
